(19) United States
(12) Patent Application Publication
(10) Pub. No.: US 2014/0042883 A1
(43) Pub. Date: Feb. 13, 2014

(54) ENCLOSURE FOR ACCOMMODATING ELECTRONIC COMPONENTS

(71) Applicant: Hon Hai Precision Industry Co., Ltd., New Taipei (TW)

(72) Inventor: CHIH-HAO LIN, New Taipei (TW)

(73) Assignee: Hon Hai Precision Industry Co., Ltd., New Taipei (TW)

(21) Appl. No.: 13/959,843

(22) Filed: Aug. 6, 2013

(30) Foreign Application Priority Data
Aug. 7, 2012 (TW) 101128496

(51) Int. Cl. H05K 5/00

(52) U.S. Cl. CPC H05K 5/0004
USPC 312/223.1

(57) ABSTRACT

An electromagnetic interference EMI-proof enclosure includes a first supporting member and a second supporting member. The first supporting member includes a first bottom plate and four side plates extending up from four edges of the bottom plate, cooperatively defining an opening therebetween. A shielding member is positioned at an end of each of the side plate away from the bottom plate. The second supporting member includes a second bottom plate, and four accommodating grooves are defined corresponding to the four shielding members. When assembled, the second bottom plate seals the opening, and the shielding members are thus accommodated and held in the accommodating grooves so as to shield electromagnetic interface received by or caused by electronic components.

### BACKGROUND

1. Technical field

The disclosure generally relates to an enclosure for accommodating electronic components, and more particularly, to an enclosure having an electromagnetic interference (EMI) shielding function.

2. Description of the Related Art

An enclosure is used to accommodate a plurality of electronic components, such as servers. When enclosures are assembled, dimensional errors of different components of the enclosures may cause gaps, and thus lead to EMI leakage and vulnerability.

Therefore, there is room for improvement within the art.

### BRIEF DESCRIPTION OF THE DRAWINGS

Many aspects of an exemplary enclosure can be better understood with reference to the following drawings. The components in the drawings are not necessarily drawn to scale, the emphasis instead being placed upon clearly illustrating the principles of the exemplary enclosure. Moreover, in the drawings, like reference numerals designate corresponding parts throughout the several views. Wherever possible, the same reference numbers are used throughout the drawings to refer to the same or like elements of an embodiment.

FIG. 1 is an isometric view of an enclosure according to an exemplary embodiment of the present disclosure, the enclosure including a first supporting member and a second supporting member overlapping each other.

FIG. 2 is an isometric view of the first supporting member of the enclosure of FIG. 1, when the first supporting member is disassembled from the second supporting member.

FIG. 3 is an enlarged view of section IV of FIG. 2 according to one embodiment of present disclosure.

FIG. 4 is an enlarged, isometric view of a part of the first supporting member of FIG. 2.

FIG. 5 illustrates an isometric view of the single second supporting member of the enclosure of FIG. 1, but viewed from another direction opposite to the viewing direction of FIG. 1.

FIG. 6 is an enlarged view of section IV of FIG. 2 according to another embodiment of present disclosure.

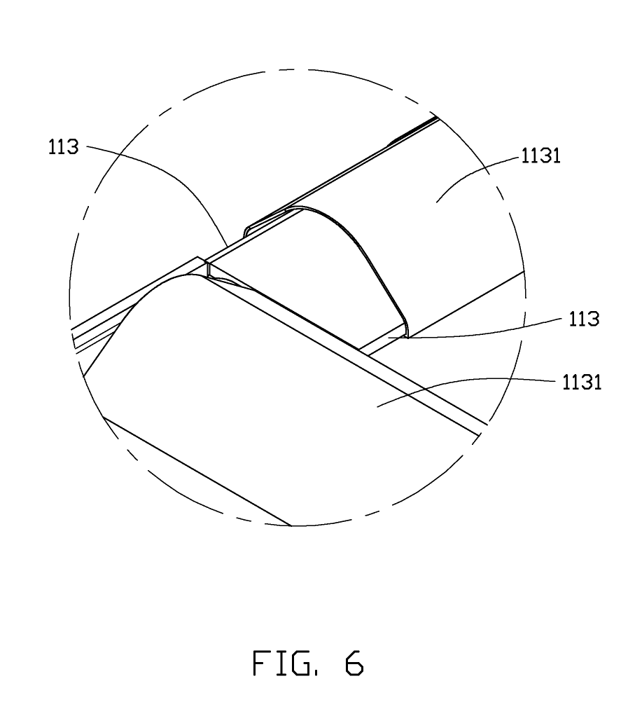

### DETAILED DESCRIPTION

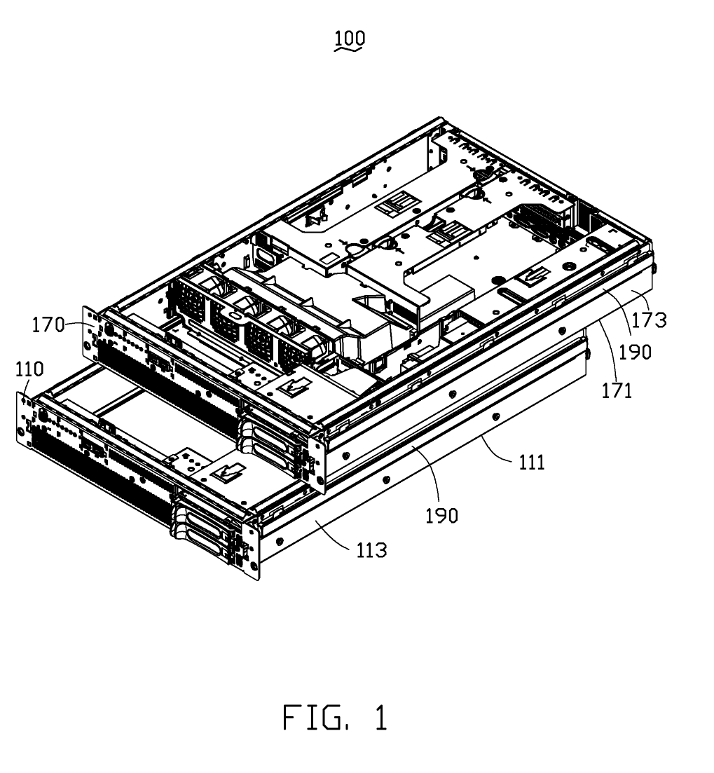

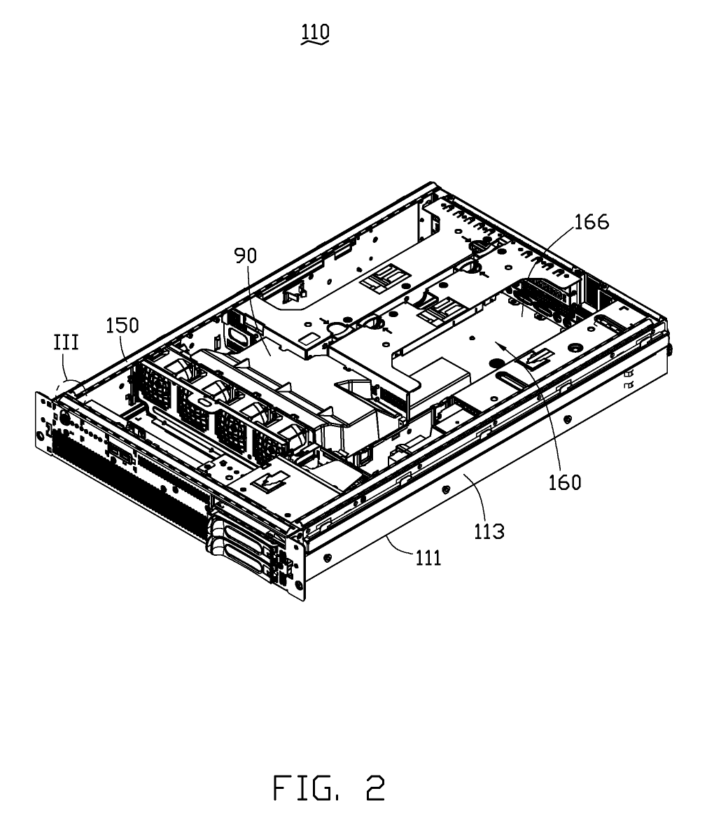

Referring to FIGS. 1-2, an enclosure 100 for accommodating servers is shown as an example. The enclosure 100 includes a first supporting member 110, and a second supporting member 170. The first supporting member 110 and the second supporting member 170 are capable of being detached. When the first supporting member 110 is engaged with the second supporting member 170, the first supporting member 110 is stacked underneath the second supporting member 170. The first supporting member 110 and the second supporting member 170 are further inserted into a metal frame (not shown). The metal frame defines several sliding grooves (not shown).

In the embodiment, the first supporting member 110 defines sliding rails 190 positioned on two external surfaces of two opposite side plates 113 of the first supporting member 110 and corresponding to the sliding grooves, so that the first supporting member 110 is capable of moving along the sliding rails 190 relative to the metal frame. In addition, the second supporting member 170 also defines sliding rails 190 at external surfaces of two opposite side plates 173 thereof and corresponding to the sliding grooves of the metal frame so as to allow the second supporting member 170 to be engaged with the metal frame.

Referring to FIG. 2, an opening 166 is defined at a top surface of the first supporting member 110 to allow a plurality of electronic components 90, such as servers, to be installed and fixed into fixing space 160 of the first supporting member 110. The first supporting member 110 further includes a bottom plate 111, and four side plates 113 extend up from four edges of the bottom plate 111 of the first supporting member 110, cooperatively defining the fixing space 160 therebetween.

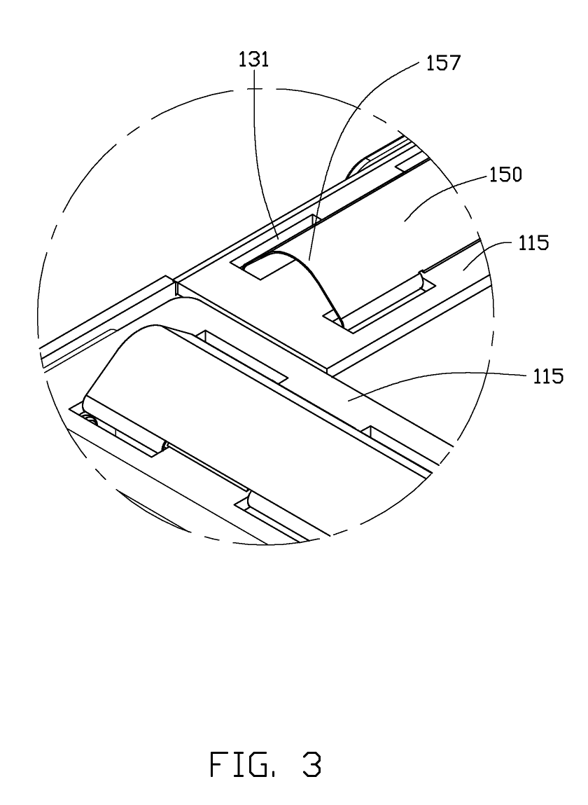

Referring to FIG. 3, the first supporting member 110 further includes fixing portions 115 and shielding members 150. The fixing portions 115 are located at inner edges of the side plates 113 and substantially perpendicular to the side plates 113. Pairs of fixing holes 131 are defined at the fixing portions 115 for engaging with the shielding members 150. Each shielding member 150 is fixed by the fixing holes 131 arranged at a fixing portion 115 and defines a protruding surface 157 higher than a planar surface of the fixing portion 115 so that when the first supporting member 110 is assembled with the second supporting member 170, the protruding surface 157 of the first supporting member 110 abuts against a bottom plate 171 of the second supporting member 170, thereby filling any gaps between the bottom plate 171 of the second supporting member 170 and the side plates 113 to shield against EMI. In the embodiment, each pair of fixing holes 131 is parallel to each other, and the two fixing holes 131 of each pair are also parallel with each other. Distances between each two adjacent pairs of the fixing holes 131 are even. Alternatively, the fixing portions 115 can be omitted, and simultaneously, the side plates 113 are be made to have a certain thickness to arrange the fixing holes 131, so that the shielding members 150 are fixed by these fixing holes 131.

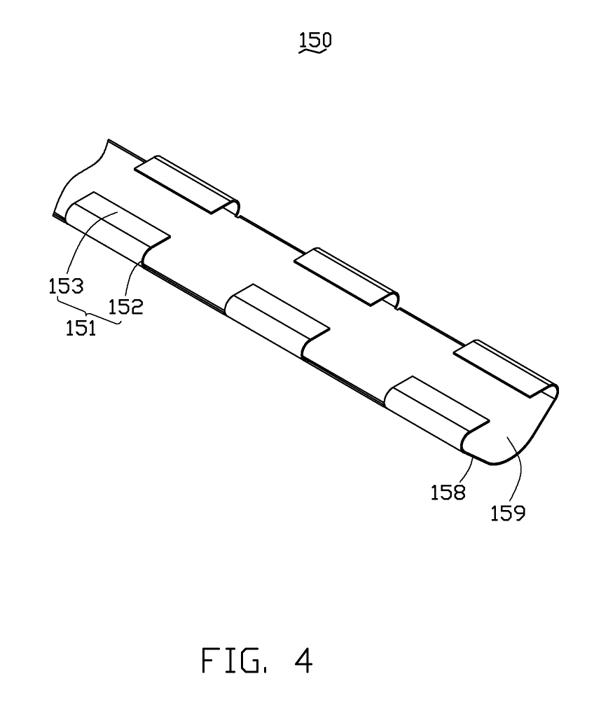

Referring to FIG. 4, the shielding member 150 includes a base plate 159 and at least one pair of fixing members 151 extending from two opposite edges 158 of the base plate 159 and bending toward a center of the base plate 159. Each fixing member 151 serves as a clamping section engagable with the fixing hole 131, and includes a resilient arm 152 and a free end 153. The resilient arm 152 inwardly extends from the opposite edges 158 of the base plate 159, and is connected between the edge 158 and the free end 153. The free end 153 is configured to be inserted into the fixing hole 131. In the embodiment, the two free ends 153 of each pair of fixing member 151 are located at a same surface and opposite to each other. The base plate 159 is shaped as an arcuate plate to define the protruding surface 157. When assembled, pairs of the free ends 153 are arranged inside pairs of the fixing holes 131. A distance between each pair of the fixing holes 131 is slightly greater than a distance between each pair of the free ends 153, and the shielding member 150 is firmly fixed on the side plate 130.

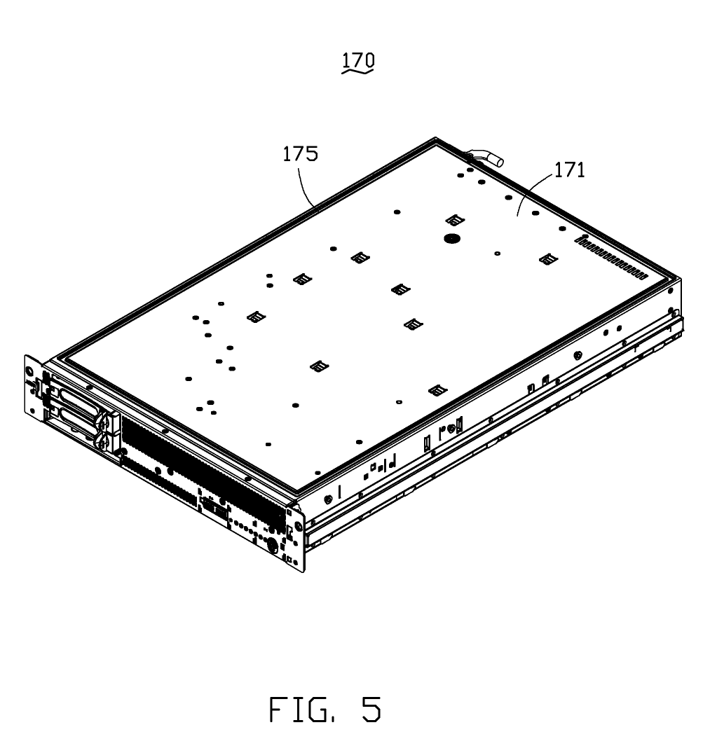

Referring to FIG. 5, an accommodating groove 175 is defined on each of the four edges of the bottom plate 171 of the second supporting member 170. The accommodating grooves 175 are positioned at a bottom surface adjacent to the side plates 113 of the first supporting member 110 when the second supporting member 170 is engaged with the first supporting member 110. When the second supporting member 170 is assembled to overlap the first supporting member 110, the shielding members 150 are accommodated in the accommodating grooves 175. Thus, the shielding members 150 and the accommodating grooves 175 fill and cover any gaps between the side plates 113 of the first supporting member 110 and the bottom plate 171 of the second supporting member 170. A base plate 171 of the second supporting member 170 is made of metal and covers the opening 166 to shield against EMI.

In another embodiment, the fixing holes 131 in a line are consecutively connected to form a chamfer. That is, two chamfers are defined on each of the fixing portion 115. The fixing members 151 are accommodated in the two chamfers to fix the shielding member 150 on the side plates 113 of the first supporting member 110.

In another embodiment, the shielding member 150 can be omitted, where the side plates 113 are made to define an arcuate surface upward to the bottom surface of the second bottom plate 171 of the second supporting member 170. Each arcuate surface which is higher than the planar surface of the side plates 113 is a part of each side plate 113 and serves as a shielding member 1131, to be engaged in the accommodating groove 175.

In the embodiment, the first supporting member 110, the second supporting member 170 and the shielding member 150 are made of metal. Therefore, the enclosure 100 which includes the first supporting member 110, the second supporting member 170 and the shielding member 150 has an inherent EMI shielding function. Further, the first supporting member 110 includes the shielding member 150 which is fixed on a fixing portion 115 located at inner edges of the side plates 113, and the shielding member 150 defines the protruding surface 157 to be higher than a planar surface of the fixing portion 115. The second supporting member 170 includes accommodating grooves 175 positioned at the bottom plate 171. When the first supporting member 170 is engaged with the first supporting member 110, the fixing portions 115 are accommodated in the accommodating grooves 175, therefore the first supporting member 110 abuts against the bottom plate 171 of the second supporting member 170. The gaps formed by the side plates 113 and the bottom plate 171 of the second supporting member 170 are blocked and filled, to improve the anti-EMI function of the enclosure 100.

It is to be understood, however, that even though numerous characteristics and advantages of the exemplary disclosure have been set forth in the foregoing description, together with details of the structure and function of the exemplary disclosure, the disclosure is illustrative only, and changes may be made in detail, especially in the matters of shape, size, and arrangement of parts within the principles of exemplary disclosure to the full extent indicated by the broad general meaning of the terms in which the appended claims are expressed.

What is claimed is:

1. An enclosure, comprising:
a first supporting member comprising a first bottom plate, a plurality of side plates extending up from each edge of the first bottom plate, and an opening corresponding defined by the first bottom plate and the plurality of side plates to accommodate electronic components; wherein the first supporting member further comprises shielding members are arranged corresponding to the side plates;
a second supporting member overlappable with the first supporting member and comprising a second bottom plate to cover the opening when the second supporting member overlaps with the first supporting member;
wherein when second bottom plate covers the opening, the shielding members abut against the second bottom plate of the second supporting member.

2. The enclosure of claim 1, wherein each shielding member defines a protruding surface upwardly protruding to the second bottom surface of the second supporting member, so that when the first supporting member is overlapped with the second supporting member, the protruding surface abuts against the second bottom plate of the second supporting member and fills gaps between the second bottom plate of the second supporting member and the side plates of the first supporting member.

3. The enclosure according to claim 1, wherein pairs of fixing holes are defined at an end surface of each side plate away from the first bottom plate for being engaged with the shielding members.

4. The enclosure according to claim 1, wherein the second bottom plate comprises accommodating grooves, each accommodating groove is defined on each edge of the second bottom plate, and the accommodating grooves are positioned at a bottom surface adjacent to the side plates of the first supporting member, when the second supporting member seals the opening, the shielding members are accommodated in the accommodating grooves.

5. The enclosure according to claim 4, wherein the first supporting member further comprises fixing portions, each fixing portion is located at inner edge of each side plate of the first supporting member, pairs of fixing holes are defined at each fixing portion for being engaged with each shielding member.

6. The enclosure according to claim 5, wherein each shielding member is fixed by the fixing holes and defines a protruding surface higher than a planar surface of the fixing portion.

7. The enclosure according to claim 5, wherein the fixing portions are perpendicular to the side plates.

8. The enclosure according to claim 5, wherein two fixing holes of each pair of the fixing holes are in parallel with each other.

9. The enclosure according to claim 5, wherein the shielding member comprises a base plate and at least a pair of fixing members extending from two opposite edges of the base plate and bending toward a center of the base plate, each fixing member servers as a clamp section for being engaged with the fixing holes and each base plate is accommodated in each accommodating groove when the second supporting member seals the opening.

10. The enclosure according to claim 9, wherein the surface of the base plate is arcuate to define a protruding surface.

11. The enclosure according to claim 9, wherein each fixing member comprises a resilient arm and a free end, the resilient arm inwardly extends from the opposite edges of the base plate, and connected between the edge of the base plate and the free end, the free end is configured to be inserted into the fixing hole and the base plate is accommodated in the accommodating groove of the second bottom plate.

12. The enclosure according to claim 11, wherein a distance between each pair of the fixing holes is greater than a distance between each pair of the free ends.

13. An enclosure for accommodating electronic components, comprising:
a first supporting member comprising a first bottom plate, a plurality of side plates extending up from each edge of the first bottom plate;
a second supporting member cooperating with the first supporting member to accommodate the electronic components, the second supporting member configured to be overlappable with the first supporting member in an assembled state, and comprising a second bottom plate, a plurality of accommodating grooves defined on a bottom surface of the second bottom plate;
wherein when the first supporting member is assembled with the second supporting member, the second bottom plate covers the first supporting member, and an end surface of each side plate away form the first bottom plate is accommodated in each accommodating groove.

14. The enclosure according to claim 13, wherein the first supporting member defines a protruding surface upwardly protruding to the second bottom surface of the second supporting member, so that when the first supporting member is overlapped with the second supporting member, the protruding surface abuts against the second bottom plate of the second supporting and fulfills gaps between the second bottom plate of the second supporting member and the side plates of the first supporting member.

15. The enclosure according to claim 13, wherein the first supporting member comprises a plurality of shielding members, each shielding member is positioned on the end surface of each side plate away from the first bottom plate, and each shielding member is accommodated in each accommodating groove.

16. The enclosure according to claim 15, wherein pairs of fixing holes are defined at an end surface of each side plate for being engaged with the shielding members, and the end surface is away from the first bottom plate.

17. The enclosure according to claim 16, wherein the shielding member comprises a base plate and at least a pair of fixing member extending from two opposite edges of the base plate and bending toward a center of the base plate, each fixing member servers as a clamp section for being engaged with the fixing holes and each base plate is accommodated in each accommodating groove when the second supporting member is engaged and overlapped the first supporting member.

18. The enclosure according to claim 17, wherein the fixing member comprises a resilient arm and a free end, the resilient arm inwardly extends from the opposite edges of the base plate, and connected between the edge of the base plate and the free end, the free end is configured to be inserted into the fixing hole and the base plate is accommodated in the accommodating groove of the second bottom plate.

19. The enclosure according to claim 18, wherein a distance of each pair of the fixing holes is greater than a distance of each pair of the free ends.

20. The enclosure according to claim 18, wherein two free ends of each pair are located at a same surface and opposite to each other.
